(19) United States
(12) Patent Application Publication
(10) Pub. No.: US 2013/0329222 A1
(43) Pub. Date: Dec. 12, 2013

(54) INSPECTING APPARATUS AND METHOD FOR MANUFACTURING SEMICONDUCTOR DEVICE

(71) Applicant: Yuji Kudo, Tokyo (JP)

(72) Inventor: Yuji Kudo, Tokyo (JP)

(21) Appl. No.: 14/001,341

(22) PCT Filed: Feb. 17, 2012
(86) PCT No.: PCT/JP2012/053865

§ 371 Date: Aug. 23, 2013

(30) Foreign Application Priority Data
Feb. 25, 2011 (JP) 2011-040926

(51) Int. Cl. G01N 21/956; H01L 21/66

(52) U.S. Cl. CPC G01N 21/956; H01L 22/12
USPC 356/237.5; 438/16

(57) ABSTRACT

There is provide an inspection apparatus configured to detect a change in shape of a pattern in the depth direction o the pattern, the apparatus including: an illumination section 20 which illuminates a wafer 5 having a periodic pattern with an illumination light having transmittance with respect to the wafer 5; a reflected diffraction light detecting section 30 which outputs a first detection signal by receiving a reflected diffraction light generated by the pattern on a surface, of the wafer, on an illumination side illuminated with the illumination light; a transmitted diffraction light detecting section 40 which outputs a second detection signal by receiving a transmitted diffraction light generated by the pattern to a back surface, of the wafer, opposite to the illumination side; and a signal processing section 51 which detects a state of the pattern based on at least one of the first and second detection signals.

### TECHNICAL FIELD

The present invention relates to an inspection apparatus for a substrate used for three-dimensional packaging, etc, and a method for producing a semiconductor device using the inspection apparatus.

### BACKGROUND ART

As a means for developing semiconductor devices and for imparting increased added value to semiconductor devices, a three-dimensional packaging technique, using Through Silicon Via (TSV: electrode passing through silicon) attracts attention, accompanying with the miniaturization of the semiconductor devices, and is vigorously developed. By stacking semiconductor chips and connecting the chips vertically via the TSV, the packaging density can be improved. Further, not only to this, the TSV has such merits as enhanced speed, low electricity consumption, etc., and is capable of realizing a high-functional and high-quality system LST. On the other hand, in the production of devices using the TSV, it is essential to perform inspection for confirmation whether or not the TSV is formed appropriately. In order to form the TSV holes each of which is deep and has a large aspect ratio (such holes is hereinafter referred to as “TSV hole pattern”) need to be dug, and the etching therefor requires a high technology and sufficient process control. Since the TSV hole pattern is a periodic pattern, the pattern inspection can be performed therefor by detecting change in the diffraction efficiency.

Conventionally, as the inspection apparatus of this type, there is known an apparatus configured such that the angle defined by a substrate to be inspected and the optical axis of an illumination system or light-receiving system is variable so as to receive a diffraction light from the substrate to be inspected. Further, there is also known an apparatus which inclines or tilts a substrate to be inspected and receives a diffraction light to detect any abnormality (defect) of a pattern of the substrate to be inspected (see, for example, Patent Literature 1).

### CITATION LIST

### Patent Literature

PATENT LITERATURE 1: U.S. Pat. No. 6,646,735

### SUMMARY OF INVENTION

### Technical Problem

However, since the conventional apparatuses use, as the illumination light or the illumination light beam, a visible light or ultraviolet light which has no transmittance with respect to a silicon wafer, the diffraction light is generated on a surface of the substrate at a very shallow portion thereof. Therefore, the conventional apparatus is capable of detecting only abnormality (defect) due to any change in the shape at a surface layer of the substrate; on the other hand, with respect to a deep pattern such as a TSV hole pattern having a depth of several tens of μm to 100 μm, the conventional apparatus cannot grasp any change wherein the shape of each of holes is changed in the depth direction of the hole.

The present invention was made in view of the problems described above, and an object of the present invention is to provide an inspection apparatus capable of detecting any change in the shape of a pattern in the depth direction of the pattern, and to provide a method for producing a semiconductor device using the inspection apparatus.

Solution to the Problem

To achieve such a task, an inspection apparatus according to a first aspect of the present invention includes:

an illumination section which illuminates a substrate having a periodic pattern formed therein with an illumination light having transmittance with respect to the substrate;

a reflected diffraction light detecting section which is configured to output a first detection signal by receiving a reflected diffraction light generated via reflective diffraction of the illumination light by the pattern on a surface, of the substrate, on an illumination side illuminated with the illumination light;

a transmitted diffraction light detecting section which is configured to output a second detection signal by receiving a transmitted diffraction light generated via transmissive diffraction of the illumination light by the pattern to a back surface, of the substrate, opposite to the illumination side; and

a state detecting section which detects a state of the pattern based on at least one of the first and second detection signals.

Note that in the inspection apparatus, the state detecting section may detect the state of the pattern based on both of the first and second detection signals.

Further, in the inspection apparatus, the pattern may be a pattern having a depth from the surface of the substrate in a depth direction orthogonal to the surface;

the state detecting section may detect a surface-vicinity state of the pattern in the vicinity of the surface based on one of the first and second detection signals, and may detect a depth-direction state of the pattern in the depth direction based on the other of the first and second detection signals.

Furthermore, in the inspection apparatus, the reflected diffraction light received may have a wavelength shorter than that of the transmitted diffraction light received.

Moreover, in the inspection apparatus, the state detecting section may detect a surface-vicinity state of a vicinity portion, of the pattern, in the vicinity of the surface of the substrate based on the first detection signal, and may detect a depth-direction state of the pattern in a depth direction of the pattern based on the second detection signal.

Further, the inspection apparatus may include a driving section which drives the transmitted diffraction light detecting section depending on an orientation of the transmitted diffraction light.

Furthermore, in the inspection apparatus, the illumination light may be a substantially parallel light.

Moreover, in the inspection apparatus, the illumination light may include an infrared light having a wavelength of not less than 0.9 μm.

Further, in the inspection apparatus, at least one of the reflected diffraction light detecting section and the transmitted diffraction light detecting section may be provided with a wavelength selecting section which selects a wavelength of the light received thereby.

Furthermore, the inspection apparatus may further include a storage section which stores at least one of the first and second detection signals while correlating at least one of the first and second signals with the state of the pattern.

Moreover, in the inspection apparatus, at least two of the transmitted diffraction light detecting section, the illumination section and the substrate may be tiltable so as to receive a transmitted diffraction light of a desired order.

Further, the inspection apparatus may further include a holder which holds the substrate;

wherein the holder may be configured to be tiltable around a tilting axis which is orthogonal to an incident plane of the substantially parallel illumination light; and

the transmitted diffraction light detecting section, the illumination section andthe reflected diffraction light detecting section may be configured to be rotatable around the tilting axis.

Furthermore, in the inspection apparatus, the illumination light may include an infrared light having a wavelength of 1.1 μm. Moreover, in the inspection apparatus, the illumination section may have a polarizing plate which is arranged to be insertable on an optical path of the illumination light

Further, a method for producing a semiconductor device according to the present invention includes:

exposing a surface of a substrate with a predetermined pattern;

performing etching on the surface of the substrate in accordance with the pattern with which the surface of the substrate has been exposed; and

performing an inspection of the substrate for which the exposure or the etching has been performed and which has the pattern formed on the surface thereof;

wherein the inspection is performed by using the inspection apparatus according to the present invention.

Furthermore, an inspection apparatus according to a second aspect of the present invention includes:

an illumination section which illuminates a substrate having a periodic pattern formed thereon with an illumination light having transmittance with respect to the substrate;

a transmitted diffraction light detecting section which is configured to output a detection signal by receiving a transmitted diffraction light generated via transmissive diffraction of the illumination light by the pattern to a back surface of the substrate, the back surface being on a side opposite to a surface, of the substrate, on an illumination side illuminated with the illumination light;

a selecting section which is configured to select at least one of a diffraction order of the transmitted diffraction light received by the transmitted diffraction light detecting section and an incident condition of the received transmitted diffraction light; and

a state detecting section which detects a state of the pattern based on the detection signal.

Note that in the inspection apparatus, at least two of the transmitted diffraction light detecting section, the illumination section and the substrate may be tiltable.

### Advantageous Effects of Invention

According to the present invention, it is possible to detect any change in the shape of the pattern in the depth direction of the pattern.

### BRIEF DESCRIPTION OF DRAWINGS

FIG. 1 is a view schematically showing the overall configuration of an inspection apparatus.

FIG. 2 is a plane view of a wafer.

FIG. 3A is a cross-sectional view of a normal hole pattern; FIG. 3B is a cross-sectional view of a hole pattern of which hole diameter is changed; and FIG. 3C is a cross-sectional view of a tapered hole pattern.

FIG. 4 is a view schematically showing examples of reflected diffraction light and transmitted diffraction light.

FIG. 5 is a flow chart showing a method for producing a semiconductor device.

### DESCRIPTION OF EMBODIMENTS

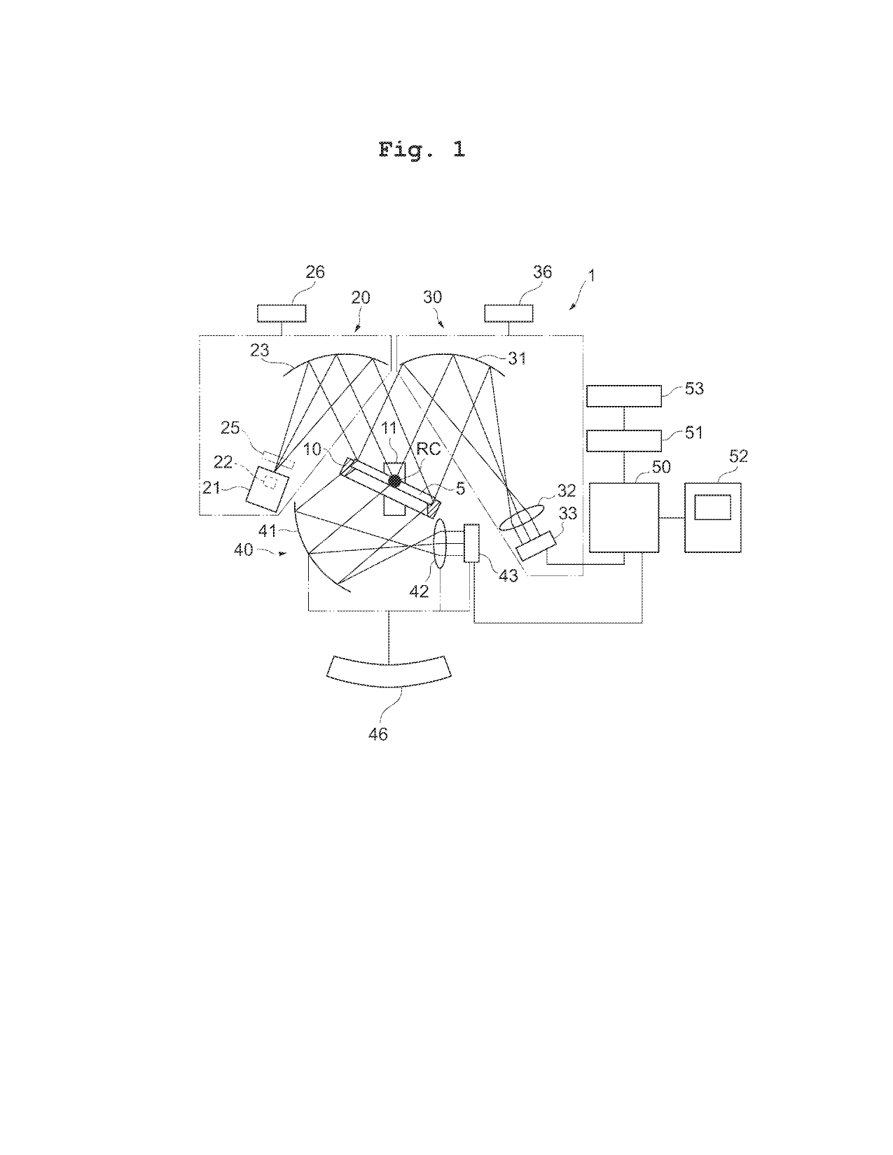

In the following, a preferred embodiment of the present invention will be explained with reference to the drawings. FIG. 1 shows an inspection apparatus 1 of the present embodiment, and an entire surface of a wafer 5 that is a silicon substrate is inspected at a time by the inspection apparatus 1. The inspection apparatus 1 of the embodiment is configured to include a wafer holder 10, an illumination section 20, a reflected diffraction light detecting section 30, a transmitted diffraction light detecting section 40, a controller 50, a signal processing section 51 and a monitor 52. After a processing (for example, etching processing) as an object to be inspected by the inspection apparatus 1 has been performed for the wafer 5, the wafer 5 is transported by a non-illustrated transporting device from a processing apparatus (for example, an etching apparatus) onto the wafer holder 10. Note that at this time, the wafer 5 as the object to be inspected is transported onto the wafer holder 10 in a state that alignment has been performed for the wafer 5, with a reference mark (a notch, an orientation flat, etc.) disposed on a pattern of the wafer 5 or at an outer edge portion of the wafer 5 used as the reference for the alignment. Note that as the wafer 5, it is possible to use a disc-shaped silicon substrate having a thickness of 725 μm. However, the size, shape, etc. of the water 5 are mere examples, and are not intended to limit the present invention in any way.

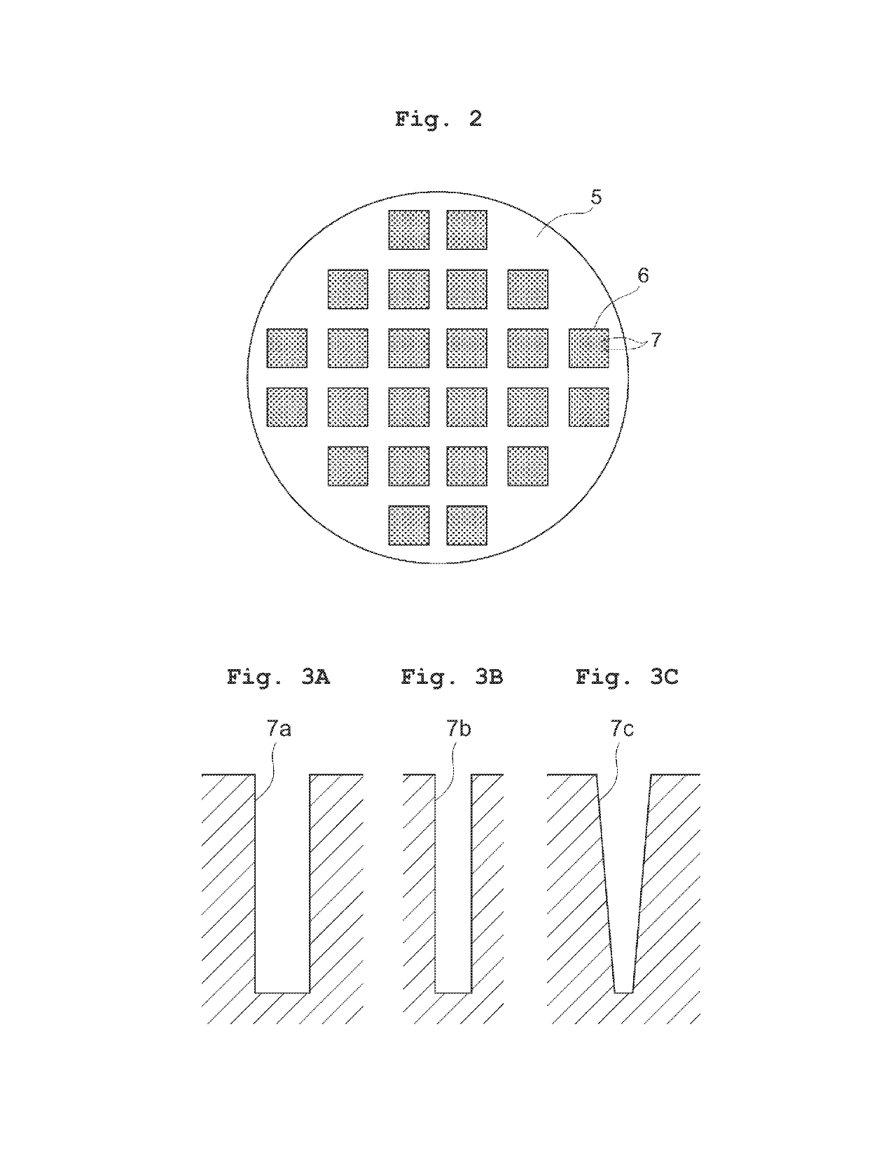

As shown in FIG. 2, a plurality of exposure shots 6 are formed on a surface of the wafer 5 formed to have a substantially disc-shape, and a TSV hole pattern 7 having periodicity is formed in each of the shots 6. Note that the TSV hole pattern 7 has a configuration wherein holes are formed in a regular arrangement in a bare wafer made of silicon (Si).

The wafer holder 10 is configured to have, for example, an annular shape conforming to the outer circumference portion of the wafer 5 so as to hold the end portion or the edge portion of the wafer 5, without blocking a light transmitting through the wafer 5. Further, it is possible to make the wafer 5 held by the wafer holder 10 be tiltable, by a tilt mechanism 11 provided on the wafer holder 10, around an axis RC passing through the center of the wafer 5 (namely, capable of tilting or rocking the wafer 5 held by the wafer holder 5 around the axis perpendicular to the light-incident plane of the wafer 5 for the illumination light). This makes it possible to adjust the incident angle of the illumination light. Note that when the wafer 5 is made to be level, while being held at the edge portion of the wafer 5, the wafer 5 bends or deflects in some cases by the self weight, with a portion in the vicinity of the center of the wafer 5 as the lowermost point. Any deflection of the wafer when performing a diffraction inspection is not desired, as the directions of the diffraction lights are not aligned. In order to avoid such deflection, the wafer 5 may be supported so that the plane of the wafer 5 is parallel to the direction of gravity. Further, when a wafer holder of the conventional vacuum chuck type is used in a case that the wafer 5 needs to be held in a state that the wafer 5 is substantially level, a scattered light generated at a corner portion of a suction groove becomes a noise. In such a case, the wafer 5 may be placed on a flat surface at which no suction groove is present, and may be held by an electrostatic chuck, etc.

The illumination section 20 is configured to have a light source section 21 which radiates an illumination light, and an illumination mirror 23 which reflects the illumination light radiated from the light source section 21 toward the surface of the wafer 5. The light source section 21 has a wavelength selecting section 22 capable of performing a selection among wavelengths from ultraviolet light to near infrared light, and radiates, as the illumination light, a divergent light flux having a predetermined wavelength which is selected by the wavelength selecting section 22. The divergent light flux (illumination light) radiated from the light source section 21 toward the illumination mirror 23 is irradiated as a substantially parallel (telecentric) light by the illumination mirror 23, since a light-exiting section of the light source section 21 is arranged at a focal plane of the illumination mirror 23 that is a concave mirror, and is irradiated on the entire surface of the wafer 5 held by the wafer holder 10. Further, the illumination section 20 has a polarizing plate 25 for polarizing the illumination light. The polarizing plate 25 is configured to be insertable on and retractable from the optical path of the illumination section 20, and to be rotatable around the optical axis of the illumination section 20. The polarizing plate 25 is capable of polarizing the illumination light in an arbitrary direction in a state that the polarizing plate 25 is inserted on the optical path of the illumination section 20, as shown in two-dot chain lines in FIG. 1.

The reflected diffraction light detecting section 30 is configured to have a first light-receiving mirror 31 which is a concave mirror, a first lens 32, and a first two-dimensional imaging element 33. A diffraction light (hereinafter referred to as “reflected diffraction light”) generated, via reflective diffraction of the illumination light by the TSV hole pattern 7 of the wafer 5 on a surface, of the wafer 5, on an illumination side illuminated with the illumination light, comes into the first light-receiving mirror 31 while remaining as being the parallel light. The reflected diffraction light reflected on the first light-receiving mirror 31 becomes a convergent light flux, and becomes a substantially parallel light flux by the first lens 32 and forms an image of the wafer 5 on the first two-dimensional imaging element 33. At this time, the first light-receiving mirror 31 and the first lens 32 cooperate to conjugate the wafer 5 and the first two-dimensional imaging element 33 with each other, and thus the image of the wafer 5 can be imaged by the first two-dimensional imaging element 33. Further, the first two-dimensional imaging element 33 photo-electrically converts the image of the wafer 5 formed on an imaging plane of the first two-dimensional imaging element 33 to generate an image signal (first detection signal), and outputs the generated image signal to the image processing section 51 via the controller 50.

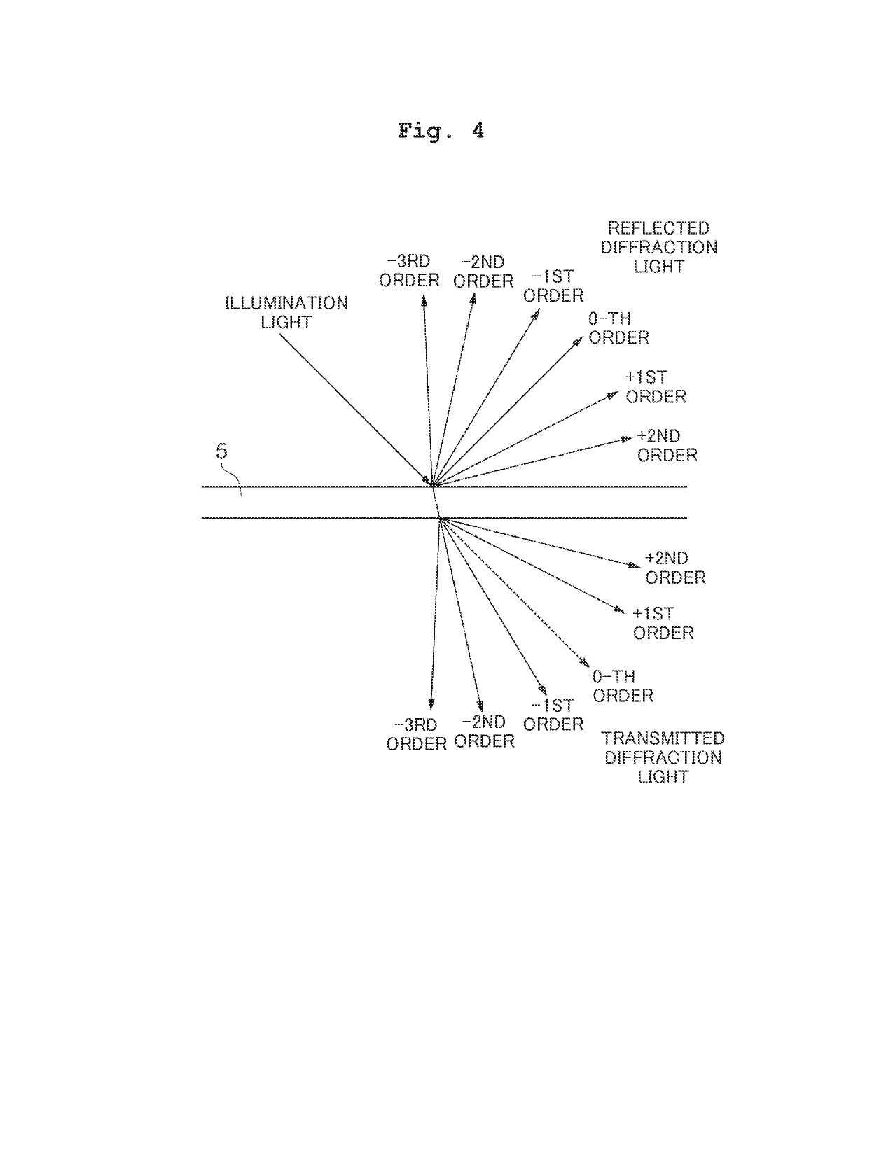

Note that a plurality of reflected diffraction lights of different orders are generated from the wafer 5, as shown for example in FIG. 4. In this embodiment, the wafer 5 is configured to be tiltable (inclinable) together with the wafer holder 10 around the above-described axis RC (see FIG. 1), and the light-incident angle of the illumination light and the light-exit angle (detected angle) of the reflected diffraction light can be changed (increased/decreased) at a time by changing the tilt angle (inclination angle) of the wafer 5, thereby making it possible to guide a reflected diffraction light having a desired, specific order toward the reflected diffraction light detecting section 30.

The transmitted diffraction light detecting section 40 is configured to have a second light-receiving mirror 41 which is a concave mirror, a second lens 42, and a second two-dimensional imaging element 43. In the embodiment, the wavelength selecting section 22 of the light source section 21 can select, as the wavelength of the illumination light, a wavelength of 1.1 μm. With this wavelength, the transmittance with respect to a silicon wafer is high. Accordingly, it is possible to detect a diffraction light (hereinafter referred to as “transmitted diffraction light) which is generated via transmissive diffraction of the illumination light by the TSV hole pattern 7 of the wafer 5 to a back surface, of the wafer 5, opposite to the surface of the wafer 5 on the illumination side illuminated with the illumination light.

The transmitted diffraction light generated from the TSV hole pattern 7 of the wafer 5 comes into the second light-receiving mirror 41 while remaining as being the parallel light flux. The transmitted diffraction light reflected by the second light-receiving mirror 41 is collected, becomes a substantially parallel light by the second lens 42, and forms an image of the wafer 5 on the second two-dimensional imaging element 43. At this time, the second light-receiving mirror 41 and the second lens 42 cooperate to conjugate the wafer 5 and the second two-dimensional imaging element 43 with each other, and thus a transmission image of the wafer 5 can be imaged by the second two-dimensional imaging element 43. Further, the second two-dimensional imaging element 43 photo-electrically converts the image of the wafer 5 formed on an imaging plane of the second two-dimensional imaging element 43 to generate an image signal (second detection signal), and outputs the generated image signal to the image processing section 51 via the controller 50.

Note that a plurality of transmitted diffraction lights of different orders are generated with respect to the wafer 5 in a direction symmetrical to the reflected diffraction lights, as shown in FIG. 4. In this embodiment, the transmitted diffraction light detecting section 40 as a whole is configured to be integrally rotatable (tiltable or inclinable) by a transmitted light detecting section-driving section 46 provided on the transmitted diffraction light detecting section 40, around the above-described axis RC (see FIG. 1) as shown in two-dot chain lines, etc., in FIG. 1. Accordingly, the light-incident angle of the illumination light and the light-exit angle (detected angle) of the transmitted diffraction light can be changed by tilting (inclining) the wafer 5 and by rotating (tilting) the entire transmitted diffraction light detecting section 40, thereby making it possible to guide a transmitted diffraction light having a desired, specific order toward the transmitted diffraction light detecting section 40. Further, the illumination section 20 is capable of changing the irradiation angle at which the illumination light is irradiated toward the wafer 5 by being tilted in an integrated manner by an illumination light driving section 26 while maintaining a state that the illumination light is oriented toward the axis RC. Further, the reflected diffraction light detecting section 30 is tiltable in an integrated manner by a reflected light detecting section-driving section 36 so that the reflected diffraction light detecting section 30 can receive a plurality of diffraction lights of different orders while maintaining a state that the reflected diffraction light detecting section 30 can receive a diffraction light from the direction of the axis RC. Note that each of the illumination light driving section 26, the reflected light detecting section-driving section 36 and the transmitted light detecting section-driving section 46 is driven upon receiving an instruction from the controller 50 based on a recipe (sequence storing the irradiation angle, the receiving angle for transmitted light and the receiving angle for reflected light) stored in a storage section built in the controller 50. In the following explanation, unless specifically explained, each of the driving and processing operations is executed by a recipe stored in the storage section built in the controller 50. Further, the controller 50 is connected to a non-illustrated input device, and is configured such that an operator uses the input device to select any one or both of the detection of the transmitted diffraction light and the detection of the reflected diffraction light and to register either one or both of these detections to the recipe.

Note that in FIG. 1, since the reflected diffraction light detecting section 30 and the transmitted diffraction light detecting section 40 are depicted on a same plane, the rotatable range of the transmitted diffraction light detecting section 40 appears to be narrow. Regarding this, for example, in a case that the first light-receiving mirror 31 is arranged while being inclined in the perpendicular direction to the sheet surface of FIG. 1 such that the first lens 32 and the first two-dimensional imaging element 33 are arrange on the far side with respect to the sheet surface of FIG. 1, and that the second light-receiving mirror 41 is arranged while being inclined in the perpendicular direction to the sheet surface of FIG. 1 such that the second lens 42 and the second two-dimensional imaging element 43 are arrange on the front side with respect to the sheet surface of FIG. 1, there is no interference between the reflected diffraction light detecting section 30 and the transmitted diffraction light detecting section 40, thereby making it possible for the transmitted diffraction light detecting section 40 to rotate at a wide angle.

The controller 50 controls the operation of each of the wafer holder 10 and tilt mechanism 11, the light source section 21, the first and second two-dimensional imaging elements 33, 43, the respective driving sections 26, 36, 46, the signal processing section 51, the monitor 52, etc. The signal processing section 51 generates an image (digital image) of the wafer 5 based on an image signal inputted from the first two-dimensional imaging element 33 or the second two-dimensional imaging element 43. Then, the image of the TSV hole pattern 7 on the wafer 5 based on the processing of the signal processing section 51 is displayed on the monitor 52. Note that since the TSV hole pattern 7 on the wafer 5 is a more minute pattern than the pixels of the first and second two-dimensional imaging elements 33 and 43, the shape of the TSV hole pattern 7 is not displayed; instead, only the information on the brightness of the image can be obtained.

In this case, if there is any abnormality (defect) in the state of the periodical structure of the pattern (for example, the hole diameter, etc.), there is a change in the diffraction efficiency, and consequently a change in the diffraction light amount, which in turn changes the intensity of the image on the two-dimensional imaging element. Accordingly, when there are an abnormal pattern and a normal pattern among a plurality of patterns 7 (exposure shots 6) on the wafer 5, then the abnormal pattern and the normal pattern are seen as being different from each other in the brightness thereof on the monitor 52. Accordingly, in a case that a brightness of a pattern previously measured by a SEM (Scanning Electron Microscope), etc., and confirmed to be normal is stored in advance, it is possible to make distinction between normal and abnormal patterns when there are patterns that are different in the brightness. Further, it is also possible to perform the detection in a case that there is a partial abnormality within a certain pattern 7 (an exposure shot area 6).

In the embodiment, an image data (signal intensity, etc.) of a normal pattern is previously stored in a storage section 53 electrically connected to the signal processing section 51. When the signal processing section 51 generates an image of the wafer 5, the signal processing section 51 compares the image data of the pattern 7 on the wafer 5 with the image data of the normal pattern stored in the storage section 53, and inspects whether any abnormality (defect) is present or absent in the TSV hole pattern 7. Then the result of the inspection by the signal processing section 51 is displayed on the monitor 2

Here, the necessity of the transmitted diffraction light detecting section 40 will be described. When an illumination light such as a visible light which does not have any transmittance with respect to a silicon wafer is used in an inspection utilizing a reflected diffraction light, the diffraction light is generated on the top layer of the wafer 5, and the light does not arrive at a deep portion inside the hole. Therefore, even in a case that there is any change in the shape in the depth direction of the hole, the diffraction efficiency is not changed. Specifically, FIG. 3A shows a normal hole pattern 7a; and FIG. 3B shows a hole pattern 7b in which the hole diameter is changed. In the hole pattern 7b shown in FIG. 3B, the diffraction efficiency is changed with respect to the normal hole pattern 7a shown in FIG. 3A, and thus the hole pattern 7b can be detected as having abnormality (defect). On the other hand, regarding a tapered hole pattern 7c as shown in FIG. 3C, since the hole diameter on the top layer is same as that of the hole pattern 7a shown in FIG. 3A, the diffraction efficiency of the hole pattern 7c is hardly changed with respect to that of the hole pattern 7a, and cannot be detected as having abnormality (defect). On the other hand, when detecting a transmitted diffraction light by the transmitted diffraction light detecting section 40 with a light having a wavelength longer than about 0.9 μm as the illumination light, the light is diffracted in the entire hole pattern including not only the top layer of the wafer 5 but also a deeper portion in the hole. Accordingly, even in a case of a hole pattern having a change in the shape as shown in FIG. 3C, the diffraction efficiency is changed, and can be detected as having abnormality (defect). Note that in a case of illuminating the hole pattern with a light having a wavelength longer than about 0.9 μm as the illumination light, a reflected diffraction light is also generated at the same time with the generation of transmitted diffraction light. Further, since the opening of the hole pattern has an edge-shaped portion, the reflected diffraction light generated from the hole pattern is relatively strong. By utilizing this phenomenon, the hole pattern is illuminated, for example, with a light having a wavelength of about 0.9 μm, and it is possible to detect the state of a portion, of the hole pattern, in the vicinity of the surface of the substrate (wafer) based on the reflected diffraction light, and to detect the state in the depth direction of the hole pattern based on the transmitted diffraction light. Namely, the state in the depth direction of the hole pattern (presence/absence of any abnormality or defect, etc.) can be detected based both on information about the transmitted diffraction light and information about the reflected diffraction light.

An inspection of wafer 5 with the inspection apparatus 1 configured as described above will be explained. Note that a wafer 5 as an object to be inspected is transported in advance on the wafer holder 10 by a non-illustrated transporting device such that a surface of the wafer 5 is oriented upward. Further, during the transportation of the wafer 5, positional information of the TSV hole pattern 7 formed in the wafer 5 is obtained by a non-illustrated alignment mechanism. This makes it possible to place the wafer 5 on the wafer holder 10 at a predetermined position and in a predetermined direction.

In a case of performing inspection utilizing reflected diffraction light, at first, an illumination light having a predetermined wavelength (for example, wavelength of 0.436 μm) selected by the wavelength selecting section 22 based on an instruction from the controller 50 is radiated from the light source section 21 toward the illumination mirror 23; the illumination light is reflected on the illumination mirror 23 and becomes a parallel light, and the parallel light is irradiated on the entire surface of the wafer 5 held by the wafer holder 10. At this time, by adjusting the tilt angle (inclination angle) of the wafer 5 held by the wafer holder 10 based on the wavelength of the illumination light exiting from the light source section 21, it is possible to receive, in the reflected diffraction light detecting section 30, a diffraction light generated via diffraction of the illumination light by the repetitive pattern that is formed regularly with a predetermined pitch (TVS hole pattern 7), thereby making it possible to form an image of the wafer 5. Specifically, the non-illustrated alignment mechanism is used to obtain the repeating direction of the repetitive pattern on the wafer 5, and to arrange the wafer 5 in advance so that the illumination direction on the surface of the wafer 5 (the direction along which the light emitted from the illumination section 20 travels toward the reflected diffraction light detecting section 30) is coincide with the repeating direction of the pattern 7; and the wafer 5 is tilted by the tilt mechanism 11 to make the setting so as to satisfy the following expression 1, provided that the pitch of the pattern 7 is “P”, the wavelength of the illumination light irradiated onto the surface of the wafer 5 is “λ”, the incident angle of the illumination light is “θ1”, and the exiting angle of the n-th order diffraction light is “θ2”.

P=n×λ/{sin(θ1)− sin(θ2)} [Expression 1]

Note that in this case, it is allowable to obtain diffraction condition by utilizing diffraction condition search based on an instruction from the controller 50, and the above setting may be made so as to obtain the diffraction light. The term “diffraction condition search” indicates a function of incrementally changing the tilt angle (inclination angle) of the wafer 5 within the angle range other than the regular reflection (specular reflection) so as to obtain images at the respective tilt angles, and to determine a tilt angle, among the tilt angles, by which the image is brightened, namely by which a diffraction light can be obtained.

The reflected diffraction light generated in the TSV hole pattern 7 of the wafer 5 is reflected on the first light-receiving mirror 31, transmits through the first lens 32 and arrives at the first two-dimensional imaging element 33, and forms an image of the wafer 5 (image by the reflected diffraction light) on the first two-dimensional imaging element 33. The first two-dimensional imaging element 33 photo-electrically converts the image of the wafer 5 formed on the imaging plane to generate an image signal (first detection signal), and outputs the generated image signal to the signal processing section 51 via the controller 50.

The signal processing section 51 generates an image (digital image) of the wafer 5 based on the image signal inputted from the first two-dimensional imaging element 33. Further, after the signal processing section 51 generates the image of the wafer 5, the signal processing section 51 compares the image data of the pattern 7 on the wafer 5 with the image date of the normal pattern (by the reflection diffraction light) stored in the storage section 53, and performs inspection regarding the presence/absence of any abnormality (defect) in the TSV hole pattern 7. Note that the inspection of the hole pattern 7 is performed for each of the exposure shots 6, and judgment is made that an abnormality is present in a case that the difference in the signal strength between the pattern 7 as the object to be inspected and the normal pattern is greater than a predetermined threshold value. On the other hand, in a case that the difference in signal strength is smaller than the threshold value, the pattern 7 as the object to be inspected is judged as being normal. Then, the result of the inspection by the signal processing section 51 and the image of the pattern 7 on the wafer 5 are displayed on the monitor 52.

On the other hand, in a case of performing inspection utilizing a transmitted diffraction light, at first, an illumination light having a predetermined wavelength (for example, wavelength of 1.1 μm) selected by the wavelength selecting section 22 is radiated from the light source section 21 toward the illumination mirror 23; the illumination light is reflected on the illumination mirror 23 and becomes a parallel light, and the parallel light is irradiated on the entire surface of the wafer 5 held by the wafer holder 10. At this time, by adjusting the wavelength of the illumination light exiting from the light source section 21, the tilt angle (inclination angle) of the wafer 5 held by the wafer holder 10 and the rotation angle of the transmitted diffraction light receiving section 40, it is possible to receive, in the transmitted diffraction light detecting section 40, a diffraction light generated via diffraction of the illumination light by the TVS hole pattern 7, thereby making it possible to form an image of the wafer 5. Specifically, the non-illustrated alignment mechanism is used so as to arrange the wafer 5 in advance so that the illumination direction on the surface of the wafer 5 (the direction along which the light emitted from the illumination section 20 travels toward the reflected diffraction light detecting section 30) is coincide with the repeating direction of the pattern 7; and the wafer 5 is tilted by the tilt mechanism 11 and the transmitted diffraction light detecting section 4i is rotated (tilted) by the transmitted light detecting section-driving section 46 to make the setting so as to satisfy the above-described expression 1.

Note that in this case, it is allowable to obtain diffraction condition by utilizing diffraction condition search, and the above setting may be made so as to obtain the diffraction light. The term “diffraction condition search” in this case indicates a function of incrementally changing the tilt angle (inclination angle) of the wafer 5 and the rotation angle of the transmitted diffraction light detecting section 40 within the angle range other than the regular reflection so as to obtain images at the respective tilt angles and the respective rotation angles, and to determine a tilt angle and a rotation angle by which the image is brightened, namely by which a diffraction light can be obtained.

The reflected diffraction light generated in the TSV hole pattern 7 of the wafer 5 is reflected on the second light-receiving mirror 41, transmits through the second lens 42 and arrives at the second two-dimensional imaging element 43, and forms an image of the wafer 5 (image by the transmitted diffraction light) on the second two-dimensional imaging element 43. The second two-dimensional imaging element 43 photo-electrically converts the image of the wafer 5 formed on the imaging plane to generate an image signal (second detection signal), and outputs the generated image signal to the signal processing section 51 via the controller 50.

The signal processing section 51 generates an image (digital image) of the wafer 5 based on the image signal inputted from the second two-dimensional imaging element 43. Further, after the signal processing section 51 generates the image of the wafer 5, the signal processing section 51 compares the image data of the pattern 7 on the wafer 5 with the image date of the normal pattern (by the transmitted diffraction light) stored in the storage section 53, and performs inspection regarding the presence/absence of any abnormality (defect) in the TSV hole pattern 7. Then, the result of the inspection by the signal processing section 51 and the image of the pattern 7 on the wafer 5 are displayed on the monitor 52.

As described above, the transmitted diffraction light detecting section 40 is provided according to the embodiment, and thus any shape change in the depth direction of the pattern 7 can be detected by utilizing the transmitted diffraction light detected by the transmitted diffraction light detecting section 40, thereby making it possible to enhance the precision of the inspection.

Further, in a case that a thin film is present on the surface of wafer 5, the inspection utilizing the transmitted diffraction light according to the embodiment is also effective. For example, there is a method wherein a mask layer (thin film) in which a hole pattern is formed is used as a hard mask to perform etching for a wafer to thereby form a TSV hole pattern 7 in a wafer. In this method, when performing etching for forming the TSV hole pattern 7, a mask layer, for example, of a SiO₂, etc. is formed on the wafer; a photoresist is coated on the mask layer; the wafer is exposed with the hole pattern by an exposure apparatus; and the etching is performed for the mask layer after the development to form the hole pattern on the mask layer. In some cases, an inspection of the TSV hole pattern 7 is desired without peeling the hard mask off. In such a situation, since there is provided a state that the thin film is present on the wafer, the inspection utilizing the reflected diffraction light generates any unevenness in image strength due to the thickness of thin film (hard mask) that is affected by the thin film interference effect due to the unevenness in the film thickness of the hard mask, thereby making it impossible to detect any change in the shape of the TSV hole pattern 7. On the other hand, an inspection using the transmitted diffraction light can be performed by performing imaging even when there is a thin film, without being affected by the thin film interference effect, as the light simply transmits through the thin film (since the reflectance of the mask layer such as SiO₂ is generally several %, and the transmitting light is not less than 90% of the light other than the reflected light).

Furthermore, each of the wafer 5 and the transmitted diffraction light detecting section 40 are tiltable according to the embodiment. Therefore, it is possible to perform an inspection utilizing transmitted diffraction lights of a same order but having different incident angles. For example, when an image is taken by receiving +1st-order transmitted diffraction light, the diffraction angle is changed when the incident angle of the illumination light is changed. With the configuration wherein the each of the wafer 5 and the transmitted diffraction light detecting section 40 is tiltable as in the embodiment, it is possible to receive transmitted diffraction lights which are of the same order but which are different in the incident angle of the illumination light. Accordingly, by performing the inspection by utilizing the above-described diffraction condition search while changing the incident angle of the illumination light in different ways and selecting an incident angle, among the incident angles, at which the diffraction efficiency is easily changed with respect to any abnormality (defect), it is possible to adjust the incident angle of the light with respect to the wall portion defining the hole pattern and extending in the depth direction of the hole pattern, and to set a sensitive diffraction condition, thereby enhancing the precision of the inspection.

Note that those described above can be realized also by tilting the illumination section 20; it is necessary that at least two of the illumination section 20, the transmitted diffraction light detecting section 40, and the wafer 5 are tiltable relative to each other or one another. Note that in order to tilt the illumination section 20, it is allowable to tilt (rotate) the entire illumination section 20 in an integrated manner by the illumination light driving section 26, or it is allowable to displace each of the light source section 21 and the illumination mirror 23 so that the optical axis of the illumination section 20 between the wafer 5 and the illumination section 20 is tilted (rotated). Further, although the transmitted diffraction light detecting section 40 is configured to be tiliable (rotatable) in an integrated manner by the transmitted light detecting section-driving section 46, it is allowable to provide a configuration wherein each of the second light-receiving mirror 41, the second lens 42 and the second two-dimensional imaging element 43 is displaced such that the optical axis of the transmitted diffraction light detecting section 40 between the wafer 5 and the transmitted diffraction light detecting section 40 is tilted (rotated).

Further, according to the embodiment, the state of the TSV hole pattern 7 can be detected by subjecting each of the image taken by the reflected diffraction light detecting section 30 and the image taken by the transmitted diffraction light detecting section 40 (first and second detection signals) to the signal processing. As described above, when using a reflected diffraction light generated by the illumination of an illumination light with a wavelength having no transmittance with respect to the wafer 5 such as a visible light, it is possible to detect only the state of the top layer of the hole. On the other hand, when using a transmitted diffraction light generated by the illumination of an illumination light with a wavelength having transmittance with respect to the wafer 5, it is possible to detect also the state of the hole in the depth direction of the hole. Accordingly, when performing the signal processing by combining the former and latter detections, it is possible to specify the kind of the abnormality (defect). For example, in a case that when a hole is judged to be abnormal both in the detections using the reflected diffraction light and the transmitted diffraction light, then the hole has such an abnormal (defect) that the diameter of the hole is entirely changed, as shown in FIG. 3B. On the other hand, in a case that when a hole is judged to be normal in the detection using the reflected diffraction light but judged to be abnormal in the detection using the transmitted diffraction light, then the hole is considered as having such an abnormal (defect) that the diameter of the hole is not changed on the surface of the hole but is changed in the depth direction of the hole, as shown in FIG. 3C. In such a manner, the combination of the reflected diffraction light and the transmitted diffraction light makes it possible to specify the kind of the abnormality (defect). Further, it is also possible to perform the detection by receiving a combination of a transmitted diffraction light and a reflected diffraction light of which orders are different from each other.

In such a case, when the wavelength selecting section 22 is provided on the illumination section 20 (light source section 21) as in the embodiment, images should be taken separately by changing the illumination wavelengths respectively for the case of detection using transmitted diffraction light and the case of detection using reflected diffraction light. On the other hand, by providing the wavelength selecting sections respectively for the reflected diffraction light detecting section 30 and the transmitted diffraction light detecting section 40, it is possible to take images at the same time by using, as the illumination light, a white light or a light containing a plurality of wavelengths in a mixed manner (for example, a light from a lump having a plurality of emission lines) and by receiving a transmitted diffraction light and a reflected diffraction light which are generated by the diffraction of such an illumination light and are different in wavelengths. Further, although one illumination section and two detecting sections (the transmitted diffraction light detecting section and the reflected diffraction light detecting section) are provided in the embodiment, it is also possible to provide an illumination section for transmissive diffraction (having a structure similar to that of the illumination section 20), instead of providing the transmitted diffraction light detecting section 40 shown in FIG. 1, thereby making it possible to take both of an image by the transmitted diffraction light and an image by the reflected diffraction light with one detecting section (reflected diffraction light detecting section 30). Note that in a case of providing two illumination sections, one light source is provided, and the optical paths (for example, optical fibers) can be switched between the two illumination sections.

Note that in the embodiment, the wavelength of the illumination light is made to be 1.1 μm. However, an illumination light having a wavelength of about not less than about 0.9 μm can realize the detection of transmitted diffraction light. As the wavelength of the light is longer, the transmittance of the light with respect to the wafer is increased, which is more convenient. However, since any excessively long wavelength lowers the sensitivity of the imaging element, the wavelength is made to be 1.1 μm in the embodiment. It should be noted, however, that since the optimum wavelength is determined depending on the balance or trade-off between the transmittance with respect to the wafer and the sensitivity to the wavelength in the imaging element, there is no limitation to the above-described wavelength. With respect to the near infrared light, the sensitivity of the imaging element is lowered and the signal-to-noise ratio is lowered in some cases. In such a situation, it is possible to use a cooling type imaging element as necessary, thereby increasing the signal-to-noise ratio.

In the embodiment, the configuration is provided so that the entirety of the wafer 5 is imaged. However, there is no limitation to this. It is allowable to provide a configuration so that a part of the wafer 5 is imaged. Note that, however, in order to detect any partial abnormality in one pattern 7 (exposure shot 6), it is possible to image at least an area greater than the exposure shot 6. In such a case, a mechanism for changing an imaging position inside the wafer 5 is necessary.

Further, in the embodiment, although the concave mirrors are used as the illumination mirror 23 and the first and second light-receiving mirrors 31 and 41, there is no limitation to this. It is possible to replace the concave mirrors with lenses. Furthermore, although the light source is built in the inspection apparatus in the embodiment, it is also allowable to take in a light generated outside the inspection apparatus, with a fiber, etc.

Moreover, in the embodiment, the reflected diffraction light detecting section 30 may be configured to be tiltable. In a configuration wherein the wafer 5 and the reflected diffraction light detecting section 30 are tiltable, it is possible to receive reflected diffraction lights which are of a same order but which are different in the incident angle of the illumination light. Accordingly, it is possible to enhance the precision of the inspection, in a similar manner as with the transmitted diffraction light detecting section 40 in order to tilt the reflected diffraction light detecting section 30, it is allowable to tilt (rotate) the entire reflected diffraction light detecting section 30 in an integrated manner about the above-described axis RC by the reflected light detecting section-driving section 36; it is allowable to provide a configuration wherein each of the first light-receiving mirror 31, the first lens 32 and the first two-dimensional imaging element 33 is displaced so as to tilt (rotate) the optical axis of the reflected diffraction light detecting section 30 between the wafer 5 and the reflected diffraction light detecting section 30. Note that regarding the reflected diffraction light, it is necessary that at least one of the illumination section 20, the reflected diffraction light detecting section 30 and the wafer 5 is tiltable. However, in a case that at least two of the illumination section 20, the reflected diffraction light detecting section 30 and the wafer 5 are tiltable, it is possible to receive reflected diffraction lights which are of a same order but which are different in the incident angle of the illumination light

In the embodiment, the wafer 5 is placed on the wafer holder 10 so that the surface of the wafer 5 is oriented upward. However, there is no limitation to this; the wafer 5 may be placed on the wafer holder 5 so that the back surface of the wafer 5 is oriented upward.

Further, the embodiment is explained by way of example of the TSV hole pattern 7. However, the object to be inspected is not limited to the TSV hole pattern 7, and may be such a pattern having a depth from the surface of the substrate and toward in the direction perpendicular to the surface. For example, the pattern may be a line-and-space pattern, without being limited to the hole pattern. Further, the embodiment is explained by way of example of the inspection of the TSV provided on the silicon wafer as the object to be inspected. However, the inspection of the embodiment is applicable also to a liquid crystal circuit board in which a liquid crystal circuit is provided on a glass substrate. Furthermore, the embodiment is explained by way of example of the inspection apparatus provided with the signal processing section 51 which performs inspection of the wafer 5 based on the image signals detected by the two-dimensional imaging elements 33 and 43. However, there is no limitation to this. The present invention is applicable also to an observation apparatus which observes images of the wafer 5 obtained by the two-dimensional imaging elements 33 and 43, without having such an inspection section provided thereon.

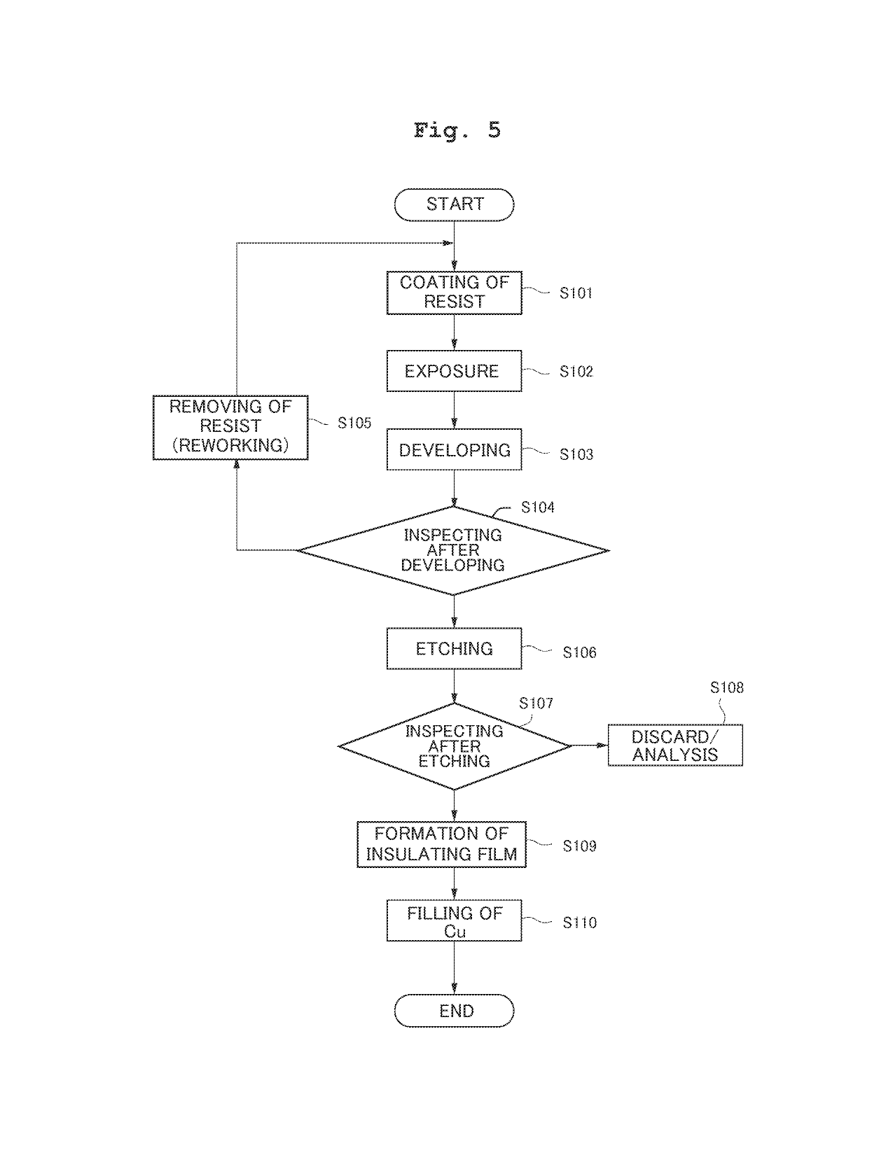

Next, a method for producing a semiconductor device in which the wafer 5 is inspected by the above-described inspection apparatus 1 will be explained with reference to the flow chart shown in FIG. 5. The flow chart of FIG. 5 shows a TSV forming process in a three-dimensional stacked-type semiconductor device. In this TSV forming process, at first, a resist is coated on a surface of a wafer (bare wafer, etc.) (Step S101). In this resist coating step, a resist coating apparatus (not shown in the drawing) is used wherein, for example, the wafer is fixed on a rotary support base with a vacuum chuck, etc., and droplets of liquid photoresist is dripped onto the surface of the wafer, and then the wafer is rotated at a high speed so as to form a thin resist film on the wafer.

Next, a predetermined pattern (hole pattern) is projected onto the surface, of the wafer, on which the resist has been coated to expose the surface with the predetermined pattern (Step S102). In this exposure step, an exposure apparatus is used to irradiate a light having a predetermined wavelength (energy radiation such as ultraviolet ray) onto the resist on the surface of the wafer, via, for example, a photomask having a predetermined pattern formed thereon, thereby transferring the mask pattern on the photomask onto the surface of the wafer.

Next, developing is performed (Step S103). In this developing step, a developing apparatus (not shown in the drawing) is used to perform a processing wherein for example the resist in an exposed portion of the wafer is dissolved by a solvent and then the resist pattern in an non-exposed portion of the wafer is allowed to remain. With this, the hole pattern is consequently formed in the resist on the surface of the wafer.

Next, a surface inspection of the surface of the wafer having the resist pattern (hole pattern) formed therein is performed (Step S104). In the inspection step performed after the developing, a surface inspecting apparatus (not shown in the drawing) is used to, for example, irradiate an illumination light onto the entire surface of the wafer, to take an image of the wafer with a diffraction light generated via diffraction of the illumination light by the resist pattern, and inspect whether there is presence/absence of any abnormality of the resist pattern, etc., from the taken image of the wafer. In this inspection step, judgment is made whether the resist pattern is satisfactory or un-satisfactory. In a case that the resist pattern is judged to be un-satisfactory, judgment is made whether an action for removing the resist and for performing the steps from the resist coating step again, namely a rework, is to be executed or not. In a case that any abnormality (defect) for which the rework is necessary is detected, the resist is removed (Step S105), and the steps from S101 to S103 are performed again. Note that the result of the inspection by the surface inspection apparatus is fed back to each of the resist coating apparatus, the exposure apparatus and the developing apparatus.

When it is confirmed that any abnormality is absent in the inspection step after the development, etching is performed (Step S106). In this etching step, an etching apparatus (not shown in the drawing) is used, for example with the remaining resist as a mask, to remove a silicon portion of the bare wafer as the underline layer, so as to form holes for forming the TSV. With this, a TSV hole pattern 7 is formed on the surface of the wafer 5.

Next, an inspection of the wafer 5, on which the pattern 7 is formed by the etching, is performed (Step S107). The inspection step after the etching is performed by using the inspection apparatus 1 according to the embodiment described above. In a case that any abnormality is detected in this inspection step, judgment is made, depending on the determined kind of the abnormality including the depth of the abnormality and the extent of the abnormality, whether as to which portion of the exposure condition (the off-axis illumination condition, focus off-set condition, etc.) of the exposure apparatus and/or which portion of the etching apparatus are/is to be adjusted, as to whether or not the wafer 5 is to be discarded, or whether or not to crack the wafer 5 further to perform detailed analysis such as observation of the cross-section of the wafer 5. In a case that any grave and widespread abnormality is found in the wafer 5 after the etching, it is not possible to perform any rework for the wafer 5. Accordingly, the wafer 5 is either discarded or subjected to analysis such as the cross-sectional observation (Step S108).

In a case that it is confirmed any abnormality is not present in the inspection step after the etching, an insulating film is formed on the side wall defining the hole (Step s109), and an electrical conductive material, such as Cu, etc., is filled in the hole at a portion at which the insulating film is formed (Step S110). With this, a through electrode for three-dimensional packaging is formed in the wafer (bare wafer).

Note that the result of the inspection in the inspection step after the etching is fed back mainly to the exposure apparatus and/or the etching apparatus. When any abnormality in the cross-sectional shape of the hole and/or any abnormality in the hole diameter are/is detected, such abnormality or abnormalities is/are fed-back as the information for adjusting the focus and/or for adjusting the dose of the exposure apparatus. When any abnormality in the shape of the hole in the depth direction of the hole and/or any abnormality in the hole depth are/is detected, such abnormality or abnormalities is/are fed-back as the information for adjusting the etching apparatus. In the etching step in the TSV forming process, a hole of which aspect ratio (depth/diameter) is high (for example, aspect ratio of 10 to 20) should be made, which is technically highly difficult, and for which adjustment by the feedback is important. As described above, it is required in the etching step to form a deep hole at an angle close to the perpendicularity, and the system referred to as Reactive Ion Etching (RIE) is widely adopted in the recent years in a case of inspection after the etching, a feedback operation (feedback management) is mainly per formed wherein monitoring is performed as to whether or not any abnormality is present in the etching apparatus, and if any abnormality is detected, the etching apparatus is shut down and adjusted. As the parameters for adjusting the etching apparatus, parameters are conceivable such as parameter for controlling the etching rate ratio between the vertical and horizontal directions, parameter for controlling the etching depth, parameter for controlling the uniformity or evenness in the wafer plane, etc.

In a case that the inspection step after the developing is executed, any abnormality in the resist coating apparatus, the exposure apparatus and/or the developing apparatus are/is detected basically in the inspection step after the developing. However, in a case that the inspection step after the developing is not executed and/or a case that any problem is found out about these apparatuses which can be revealed only after performing the etching, the feedback is performed for each of these apparatuses (adjustment is performed for each of these apparatuses).

On the other hand, the result of inspection in the inspection step after the etching can be fed forward to a subsequent step(s) thereafter. For example, in a case that a part of the chips in the wafer 5 is judged to be abnormal (defective) in the inspection step after the etching, the information about the abnormality (defect) is transmitted to and stored in a host computer (not shown in the drawing) which manages the process via on-line connection with the above-described inspection apparatus 1, and the information is used for the management in an inspection and/or measurement performed in a subsequent process or processes such that the abnormal portion (chip) is not used, etc., or is utilized so as not to perform any unnecessary electrical test at a stage that the device is finally completed as a final product, etc. Further, in a case that the area or size of the abnormal portion is found out to be great from the result of the inspection in the inspection step after the etching, the information regarding the abnormality can be used for adjusting the parameter for formation of insulating film and/or the parameter for filling Cu depending on the information regarding the abnormality, in order to mitigate any effect on a satisfactory portion, of the wafer, that is different from the abnormal portion.

According to the method for producing semiconductor device of the embodiment, the inspection step after the etching is performed by using the inspection apparatus 1 according to the above-described embodiment. Therefore, it is possible to detect any change in the shape in the depth direction of the pattern 7, and to enhance the precision of the inspection, thereby making it possible to enhance the efficiency for producing semiconductor devices.

Note that in the TSV forming process described above, the TSV is formed in a first or initial stage before forming any element on the wafer. However, there is no limitation to this, and it is allowable to form the TSV after forming any element, or to form the TSV in any intermediate step in the element formation. Note that, in such a case, although the transparency with respect to the infrared light is lowered as a result of ion implantation, etc., performed in the element formation process, the lowering of transparency does not necessarily lead to the complete opacity. Accordingly, it is allowable to select the wavelength and/or to adjust the amount of illumination light in view of the amount of change in the transparency. Further, with a production line of such a system, it is possible to perform an inspection not affected by the lowering in transparency due to the ion implantation, by performing an inspection for forming the TSV in a bare wafer, for the purpose of setting the condition for the production line and of performing the quality control.

### INDUSTRIAL APPLICABILITY

The present application is applicable to an inspection apparatus used in an inspection step performed after etching in the semiconductor device production. With this, it is possible to enhance the inspection precision of the inspection apparatus, and to improve the efficiency for producing semiconductor devices.

### REFERENCE SIGNS LIST

1: inspection apparatus
5: wafer
7: TSV hole pattern
10: wafer holder
11: tilt mechanism
20: illumination section
22: wavelength selecting section
30: reflected diffraction light detecting section
40: transmitted diffraction light detecting section
46: transmitted light detecting section-driving section
50: controller
51: signal processing section (state detecting section)
53: storage section

1. An inspection apparatus comprising:
an illumination section which is configured to illuminates a substrate having a periodic pattern formed therein with an illumination light having transmittance with respect to the substrate;
a reflected diffraction light detecting section which is configured to output a first detection signal by receiving a reflected diffraction light generated via reflective diffraction of the illumination light by the pattern on a surface, of the substrate, on an illumination side illuminated with the illumination light;
a transmitted diffraction light detecting section which is configured to output a second detection signal by receiving a transmitted diffraction light generated via transmissive diffraction of the illumination light by the pattern to a back surface, of the substrate, opposite to the illumination side; and
a state detecting section which is configured to detects a state of the pattern based on at least one of the first and second detection signals.

2. The inspection apparatus according to claim 1, wherein the state detecting section is configured to detects the state of the pattern based on both of the first and second detection signals.

3. The inspection apparatus according to claim 1, wherein the pattern is a pattern having a depth from the surface of the substrate in a depth direction orthogonal to the surface;
the state detecting section is configured to detect a surface-vicinity state of the pattern in the vicinity of the surface based on one of the first and second detection signals, and to detect a depth-direction state of the pattern in the depth direction based on the other of the first and second detection signals.

4. The inspection apparatus according to claim 3, wherein the reflected diffraction light received has a wavelength shorter than that of the transmitted diffraction light received.

5. The inspection apparatus according to claim 1, wherein that wherein the state detecting section is configured to detect a surface-vicinity state of a vicinity portion, of the pattern, in the vicinity of the surface of the substrate based on the first detection signal, and to detect a depth-direction state of the pattern in a depth direction of the pattern based on the second detection signal.

6. The inspection apparatus according to claim 1, further comprising a driving section which is configured to drive the transmitted diffraction light detecting section depending on an orientation of the transmitted diffraction light.

7. The inspection apparatus according to claim 1, wherein the illumination light is a substantially parallel light.

8. The inspection apparatus according to claim 1, wherein the illumination light includes an infrared light having a wavelength of not less than 0.9 μm.

9. The inspection apparatus according to claim 1, wherein at least one of the reflected diffraction light detecting section and the transmitted diffraction light detecting section includes a wavelength selecting section which is configured to select a wavelength of the light received thereby.

10. The inspection apparatus according to claim 1, further comprising a storage section which is configured to store at least one of the first and second detection signals while correlating at least one of the first and second signals with the state of the pattern.

11. The inspection apparatus according to claim 1, at least two of the transmitted diffraction light detecting section, the illumination section and the substrate are tiltable so as to receive a transmitted diffraction light of a desired order.

12. The inspection apparatus according to claim 7, further comprising a holder which is configured to hold the substrate;
wherein the holder is configured to be tiltable about a tilting axis which is orthogonal to an incident plane of the substantially parallel illumination light; and
the transmitted diffraction light detecting section, the illumination section and the reflected diffraction light detecting section are configured to be rotatable around the tilting axis.

13. The inspection apparatus according to claim 8, wherein the illumination light includes an infrared light having a wavelength of 1.1 μm.

14. The inspection apparatus according to claim 1, wherein the illumination section has a polarizing plate which is arranged to be insertable on an optical path of the illumination light.

15. A method for producing a semiconductor device, comprising:
exposing a surface of a substrate with a predetermined pattern;
performing etching on the surface of the substrate in accordance with the pattern with which the surface of the substrate has been exposed; and
performing an inspection of the substrate for which the exposure or the etching has been performed and which has the pattern formed on the surface thereof:
wherein the inspection of the substrate is performed by using the inspection apparatus as defined in claim 1.

16. An inspection apparatus comprising:
an illumination section which is configured to illuminate a substrate having a periodic pattern formed thereon with an illumination light of an infrared region;
a transmitted diffraction light detecting section which is configured to output a detection signal by receiving a transmitted diffraction light generated via transmissive diffraction of the illumination light by the pattern to a back surface of the substrate, the back surface being on a side opposite to a surface, of the substrate, on an illumination side illuminated with the illumination light;
a selecting section which is configured to select at least one of a diffraction order of the transmitted diffraction light received by the transmitted diffraction light detecting section and an incident condition of the illumination light; and
a state detecting section which is configured to detect a state of the pattern based on the detection signal.

17. The inspection apparatus according to claim 16, wherein at least two of the transmitted diffraction light detecting section, the illumination section and the substrate are tiltable.

18. The inspection apparatus according to claim 16, wherein the illumination light includes an infrared light having a wavelength of not less than 0.9 μm.
